(19) United States
(12) Patent Application Publication
(10) Pub. No.: US 2024/0175120 A1
(43) Pub. Date: May 30, 2024

(54) LOW RESISTIVITY GAPFILL

(71) Applicant: Applied Materials, Inc., Santa Clara, CA (US)

(72) Inventors: Tsung-Han Yang, San Jose, CA (US); Zhen Liu, Santa Clara, CA (US); Yongqian Gao, Sunnyvale, CA (US); Wenting Hou, San Jose, CA (US); Rongjun Wang, Dublin, CA (US)

(73) Assignee: Applied Materials, Inc., Santa Clara, CA (US)

(21) Appl. No.: 18/512,894

(22) Filed: Nov. 17, 2023

Related U.S. Application Data
(60) Provisional application No. 63/429,127, filed on Nov. 30, 2022.

(51) Int. Cl. C23C 16/04; C23C 16/06; H01L 21/768; H01L 23/532

(52) U.S. Cl. CPC C23C 16/045; C23C 16/06; H01L 21/76843; H01L 21/76876; H01L 21/76877; H01L 23/53266

(57) ABSTRACT

Embodiments of the disclosure relate to methods for metal gapfill with lower resistivity. Specific embodiments provide methods of forming a tungsten gapfill without a high resistance nucleation layer. Some embodiments of the disclosure utilize a nucleation underlayer to promote growth of the metal gapfill.

### CROSS-REFERENCE TO RELATED APPLICATIONS

This application claims priority to U.S. Provisional Application No. 63/429,127, filed Nov. 30, 2022, the entire disclosure of which is hereby incorporated by reference herein.

### TECHNICAL FIELD

Embodiments of the present disclosure pertain to methods for deposition of metal gapfill within substrate features. More particularly, embodiments of the disclosure are directed to methods which provide gapfill with improved resistivity.

### BACKGROUND

Gapfill process are integral to several semiconductor manufacturing processes. A gapfill process can be used to fill a gap (or feature) with an insulating or conducting material. For example, shallow trench isolation, inter-metal dielectric layers, passivation layers, dummy gate, are all typically implemented by gapfill processes.

As device geometries continue to shrink (e.g., critical dimensions<20 nm, <10 nm, and beyond), decreased metal volumes create higher resistivity for metal interconnects.

Typically, for tungsten gapfill, a nucleation layer comprising silicon or boron is deposited on top of PVD tungsten liners before forming a tungsten bulk fill to promote the formation/growth of the bulk fill on the PVD liner. However, these nucleation layers lead to the formation of a relatively high resistance stack due to the presence of BW and/or WSi.

Accordingly, there is a need for gapfill methods which provide lower resistivity. Specifically, there is a need for gapfill methods without the use of a nucleation layer between a PVD liner and bulk fill materials.

### SUMMARY

One or more embodiments of the disclosure are directed to a method of metal gapfill. The method comprises exposing a substrate surface with at least one feature therein to a nucleation presoak to form a nucleation underlayer. The feature extends a depth from the substrate surface to a bottom and has two sidewalls. A metal liner is deposited on the nucleation underlayer by physical vapor deposition (PVD). A metal gapfill is deposited on the metal liner and the nucleation underlayer.

Additional embodiments of the disclosure are directed to a method of metal gapfill. The methods comprise exposing a substrate surface with at least one feature therein to a nucleation presoak comprising silane to form a silicon nucleation underlayer. The feature extends a depth from the substrate surface to a bottom and has two sidewalls. A metal liner comprising tungsten is deposited on the silicon nucleation underlayer by physical vapor deposition (PVD). A metal gapfill comprising tungsten is deposited on the metal liner and the silicon nucleation underlayer.

Further embodiments of the disclosure are directed to a method of metal gapfill. The methods comprise exposing a substrate surface with at least one feature therein to a nucleation presoak comprising diborane to form a boron nucleation underlayer. The feature extends a depth from the substrate surface to a bottom and has two sidewalls. A metal liner comprising tungsten is deposited on the boron nucleation underlayer by physical vapor deposition (PVD). A metal gapfill comprising tungsten is deposited on the metal liner and the boron nucleation underlayer.

### BRIEF DESCRIPTION OF THE DRAWINGS

So that the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a deposition method according to one or more embodiment;

FIGS. 2A-2D illustrate a cross-sectional view of a substrate during processing according to one or more embodiment; and

FIG. 3 illustrates a schematic top-view diagram of a multi-chamber processing system according to one or more embodiment.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of +15% or less, of the numerical value. For example, a value differing by +14%, +10%, +5%, +2%, +1%, +0.5%, or +0.1% would satisfy the definition of “about.”

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate surface” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The substrate surface may have one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls and a bottom extending into the substrate, and vias which have one or more sidewall extending into the substrate to a bottom.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

Embodiments of the disclosure advantageously provide methods for depositing metal gapfill with low resistivity. Specific embodiments advantageously provide methods of depositing metal gapfill with reduced resistivity relative to methods which utilize a nucleation layer on a metal liner. In some embodiments, the metal of the disclosed metal liner and/or metal gapfill comprises tungsten.

The embodiments of the disclosure are described by way of the Figures, which illustrate processes, substrates and apparatus in accordance with one or more embodiments of the disclosure. The processes, schema and resulting substrates shown are merely illustrative of the disclosed processes, and the skilled artisan will recognize that the disclosed processes are not limited to the illustrated applications.

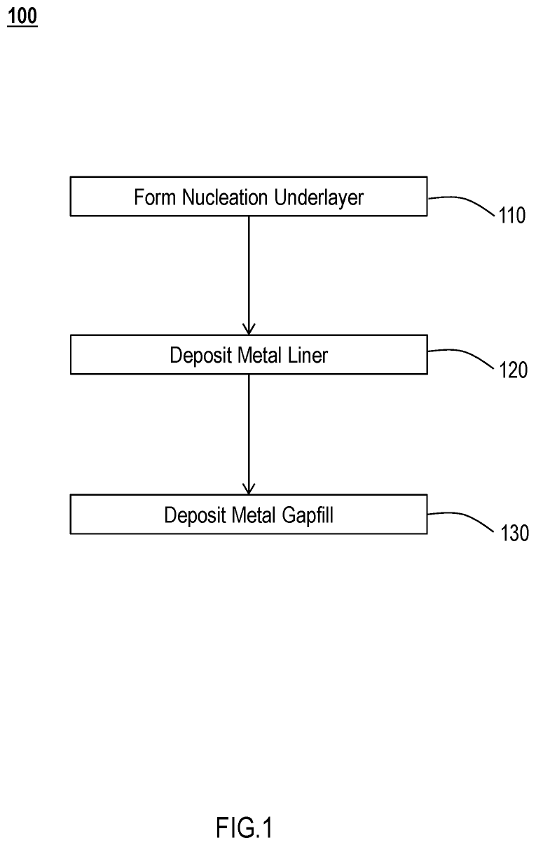

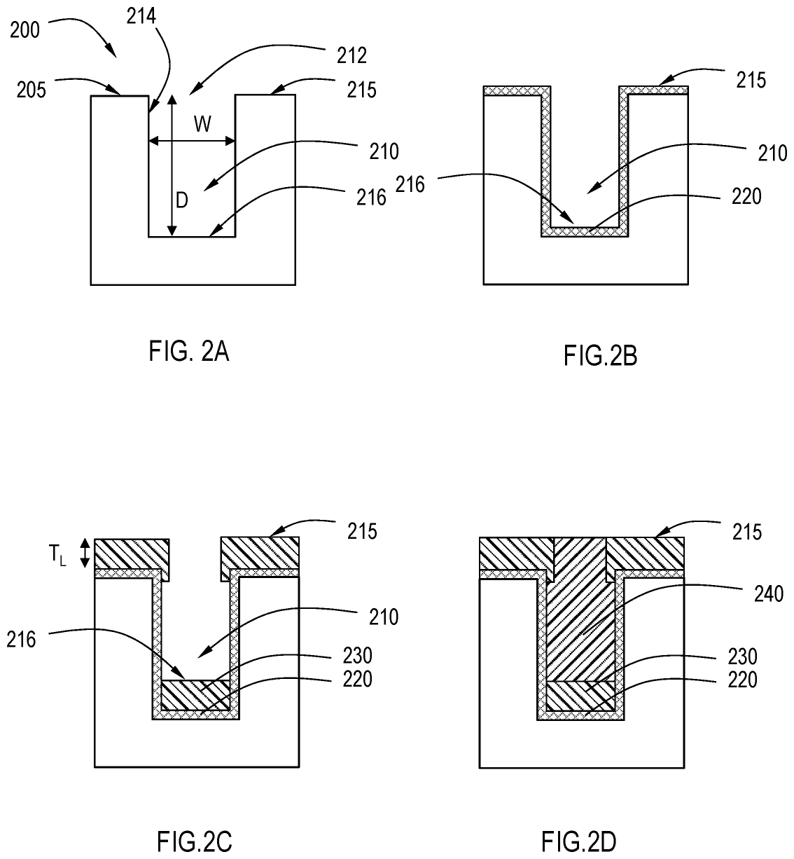

Referring to FIGS. 1-2D, the disclosure relates to a method 100 of depositing a metal gapfill. FIG. 1 depicts a process flow diagram of a deposition method 100 in accordance with one or more embodiment of the present disclosure. FIGS. 2A-2D depict a substrate 200 during processing according to one or more embodiment of the present disclosure.

FIG. 2A illustrates a substrate 200 with a substrate surface 205. As identified above, the substrate surface refers to the exposed surface of the substrate upon which a layer may be formed. The substrate surface 205 has at least one feature 210 formed therein. While only a single feature is shown in the Figures, one skilled in the art will recognize that a plurality of features will be affected by the disclosed methods, each in a similar manner.

The at least one feature 210 has an opening 212 with a width W. The opening 212 is formed in a top surface 215 of the substrate 200. The feature 210 also has one or more sidewall 214 and extends a depth D from the top surface 215 to a bottom 216. While straight, vertical sidewalls are shown in the Figures, the disclosed methods may also be performed on slanted, irregular or reentrant sidewalls.

In some embodiments, the width W of the opening 212 is greater than or equal to about 10 nm, greater than or equal to about 15 nm, greater than or equal to about 20 nm, greater than or equal to about 25 nm, greater than or equal to about 30 nm, or greater than or equal to about 35 nm. In some embodiments, the width W is in a range of about 5 nm to about 15 nm, or in a range of about 10 nm to about 35 nm.

In some embodiments, the depth D of the feature 210 is greater than or equal to about 50 nm, greater than or equal to about 75 nm, greater than or equal to about 100 nm, greater than or equal to about 150 nm, greater than or equal to about 200 nm, or greater than or equal to about 250 nm. In some embodiments, the depth D is in a range of about 50 nm to about 250 nm, or in a range of about 200 nm to about 250 nm.

Those skilled in the art will recognize the increasing challenge of depositing metal gapfill in features of narrowing width (also known as critical dimension (CD)) and/or increasing depth. The aspect ratio of the at least one feature 210 is defined as the depth D of the feature 210 divided by the width W. In some embodiments, the at least one feature has an aspect ratio (D:W) greater than or equal to about 2:1, greater than or equal to about 5:1, greater than or equal to about 10:1, or greater than or equal to about 20:1.

Referring to FIGS. 1 and 2B, the method 100 begins with operation 110. At 110, a nucleation underlayer 220 is formed on the substrate surface 205 and within the at least one feature 210. In some embodiments, as shown in FIG. 2B, the nucleation underlayer 220 is continuous and deposited on the top surface 215, the sidewalls 214 and the bottom 216.

At operation 110, the nucleation underlayer 220 is formed by exposing the substrate surface to a nucleation presoak. In some embodiments, the nucleation presoak comprises a silicon compound. In some embodiments, the nucleation presoak comprises a boron compound. As used herein, a “silicon compound” or a “boron compound” is any material capable of forming a layer of silicon or boron, respectively, on the substrate surface.

In some embodiments, the silicon compound comprises or consists essentially of silane (SiH₄), disilane, trislane, tertrasilane, cyclopentasilane, or cyclohexasilane. In some embodiments, the boron compound comprises or consists essentially of borane, diborane (B₂H₆), triborane, tetraborane, or cycloboranes. As used in this regard, a process gas which “consists essentially of” a stated material comprises greater than about 95%, greater than about 98%, greater than about 99%, or greater than about 99.5% of the stated material on a molar basis, excluding any inert diluent or carrier gases.

In some embodiments, the nucleation underlayer is substantially conformal. As used in this regard, a layer which is “substantially conformal” has an average thickness which varies by less than 10%, less than 5% or less than 2% of the average thickness of the layer. In some embodiments, the nucleation underlayer has an average thickness of less than 10 Å or less than 5 Å. In some embodiments, the nucleation underlayer comprises 1-2 monolayers of silicon and/or boron.

In some embodiments, operation 110 represents chemical vapor deposition (CVD) process. In some embodiments, the temperature of the CVD process is in a range of about 250° C. to about 450° C., in a range of about 250° C. to about 350° C., or in a range of about 350° C. to about 450° C. In some embodiments, the CVD process is performed without plasma.

The method 100 continues to operation 120 after formation of the nucleation underlayer 220. Referring to FIG. 2C, the method 100 continues at operation 120 where a metal liner 230 is deposited on the nucleation underlayer 220. In some embodiments, the metal liner 230 is deposited by a physical vapor deposition process. In some embodiments, the metal liner is not continuous. In some embodiments, the metal liner does not cover the sidewall 214 of the feature 210. In some embodiments, the average thickness of the metal liner 230 outside of the at least one feature 210 is less than or equal to about 50 Å.

Without being bound by theory, it is believed that the presence of the nucleation underlayer 220 facilitates the growth of the metal gapfill 240 (described below) in areas that the metal liner 230 fails to cover. Further, the order of formation prevents the nucleation underlayer 220 from forming high resistance BW and/or WSi between the metal liner 230 and the metal gapfill 240.

The method 100 continues to operation 130 after formation of the metal liner 230. Referring to FIG. 2D, the method 100 continues at operation 130 where a metal gapfill 240 is deposited on the metal liner 230 and the nucleation underlayer 220. In some embodiments, the metal gapfill 240 is deposited by an atomic layer deposition (ALD) process. In some embodiments, the metal gapfill 240 is deposited by a chemical vapor deposition (CVD) process. In some embodiments, the metal gapfill 240 is deposited by an atomic layer deposition (ALD) process followed by a chemical vapor deposition (CVD) process.

In some embodiments, the metal gapfill 240 is formed directly on the metal liner 230 and the nucleation underlayer 220. Stated differently, In some embodiments, the metal gapfill 240 is deposited without the typical nucleation layer on the metal liner 230. As stated above, without being bound by theory, it is believed that the disclosed methods provide metal gapfill without the use or formation of a high resistance nucleation layer. In some embodiments, the metal liner 230 and the metal gapfill 240 are referred to as a metal stack. In some embodiments, the nucleation underlayer does not increase the resistance of the metal stack. Further, the inventors have surprisingly found that the presence of the nucleation underlayer 220 does not adversely affect the adhesion of the metal stack to the underlying substrate.

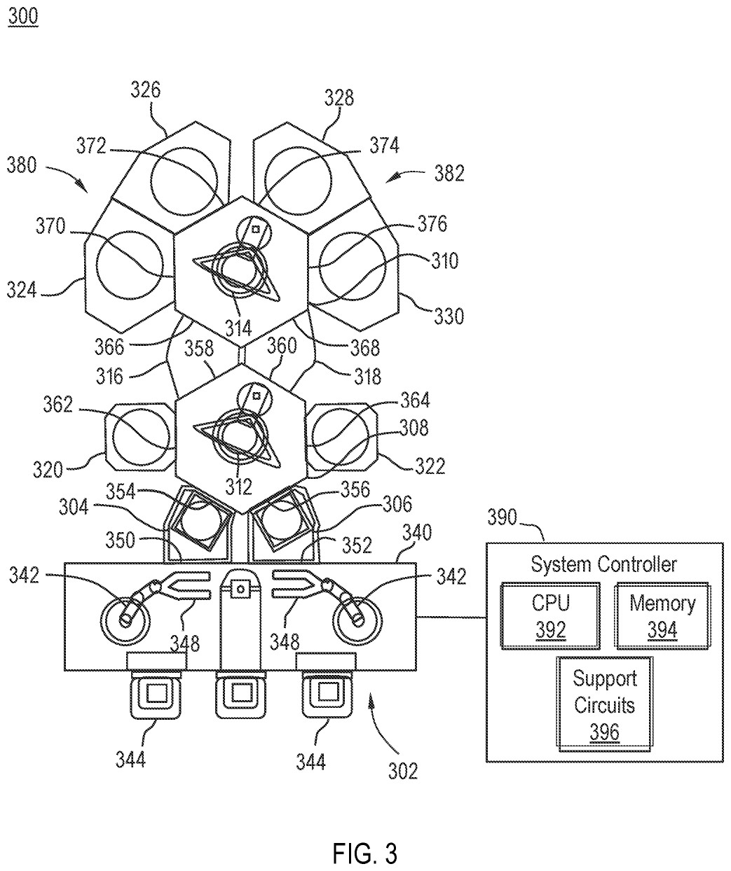

FIG. 3 is a schematic top-view diagram of an exemplary multi-chamber processing system 300 according to embodiments of the present disclosure. The processing system 300 generally includes a factory interface 302, load lock chambers 304, 306, transfer chambers 308, 310 with respective transfer robots 312, 314, holding chambers 316, 318, and processing chambers 320, 322, 324, 326, 328, 330. As detailed herein, wafers in the processing system 300 can be processed in and transferred between the various chambers without exposing the wafers to an ambient environment exterior to the processing system 300 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 300. Accordingly, the processing system 300 may provide for an integrated solution for some processing of wafers.

Examples of a processing system that may be suitably modified in accordance with the teachings provided herein include the Endura®, Producer®, or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 3, the factory interface 302 includes a docking station 340 and factory interface robots 342 to facilitate transfer of wafers. The docking station 340 is configured to accept one or more front opening unified pods (FOUPs) 344. In some examples, each factory interface robot 342 generally comprises a blade 348 disposed on one end of the respective factory interface robot 342 configured to transfer the wafers from the factory interface 302 to the load lock chambers 304, 306.

The load lock chambers 304, 306 have respective ports 350, 352 coupled to the factory interface 302 and respective ports 354, 356 coupled to the transfer chamber 308. The transfer chamber 308 further has respective ports 358, 360 coupled to the holding chambers 316, 318 and respective ports 362, 364 coupled to processing chambers 320, 322. Similarly, the transfer chamber 310 has respective ports 366, 368 coupled to the holding chambers 316, 318 and respective ports 370, 372, 374, 376 coupled to processing chambers 324, 326, 328, 330. The ports 354, 356, 358, 360, 362, 364, 366, 368, 370, 372, 374, 376 can be, for example, slit valve openings with slit valves for passing wafers therethrough by the transfer robots 312, 314 and for providing a seal between respective chambers to prevent a gas from passing between the respective chambers. Generally, any port is open for transferring a wafer therethrough. Otherwise, the port is closed.

The load lock chambers 304, 306, transfer chambers 308, 310, holding chambers 316, 318, and processing chambers 320, 322, 324, 326, 328, 330 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 342 transfers a wafer from a FOUP 344 through a port 350 or 352 to a load lock chamber 304 or 306. The gas and pressure control system then pumps down the load lock chamber 304 or 306. The gas and pressure control system further maintains the transfer chambers 308, 310 and holding chambers 316, 318 with an interior low pressure or vacuum environment (which may include an inert gas). Hence, the pumping down of the load lock chamber 304 or 306 facilitates passing the wafer between, for example, the atmospheric environment of the factory interface 302 and the low pressure or vacuum environment of the transfer chamber 308.

With the wafer in the load lock chamber 304 or 306 that has been pumped down, the transfer robot 312 transfers the wafer from the load lock chamber 304 or 306 into the transfer chamber 308 through the port 354 or 356. The transfer robot 312 is then capable of transferring the wafer to and/or between any of the processing chambers 320, 322 through the respective ports 362, 364 for processing and the holding chambers 316, 318 through the respective ports 358, 360 for holding to await further transfer. Similarly, the transfer robot 314 is capable of accessing the wafer in the holding chamber 316 or 318 through the port 366 or 368 and is capable of transferring the wafer to and/or between any of the processing chambers 324, 326, 328, 330 through the respective ports 370, 372, 374, 376 for processing and the holding chambers 316, 318 through the respective ports 366, 368 for holding to await further transfer. The transfer and holding of the wafer within and among the various chambers can be in the low pressure or vacuum environment provided by the gas and pressure control system.

The processing chambers 320, 322, 324, 326, 328, 330 can be any appropriate chamber for processing a wafer. In some embodiments, the processing chamber 320 can be capable of performing a nucleation presoak, the processing chamber 322 can be capable of performing a PVD deposition process, and the processing chamber 324 can be capable of performing a ALD and/or CVD deposition process.

A system controller 390 is coupled to the processing system 300 for controlling the processing system 300 or components thereof. For example, the system controller 390 may control the operation of the processing system 300 using a direct control of the chambers 304, 306, 308, 316, 318, 310, 320, 322, 324, 326, 328, 330 of the processing system 300 or by controlling controllers associated with the chambers 304, 306, 308, 316, 318, 310, 320, 322, 324, 326, 328, 330. In operation, the system controller 390 enables data collection and feedback from the respective chambers to coordinate performance of the processing system 300.

The system controller 390 generally includes a central processing unit (CPU) 392, memory 394, and support circuits 396. The CPU 392 may be one of any form of a general-purpose processor that can be used in an industrial setting. The memory 394, or non-transitory computer-readable medium, is accessible by the CPU 392 and may be one or more of memory such as random-access memory (RAM), read only memory (ROM), floppy disk, hard disk, or any other form of digital storage, local or remote. The support circuits 396 are coupled to the CPU 392 and may comprise cache, clock circuits, input/output subsystems, power supplies, and the like. The various methods disclosed herein may generally be implemented under the control of the CPU 392 by the CPU 392 executing computer instruction code stored in the memory 394 (or in memory of a particular process chamber) as, for example, a software routine. When the computer instruction code is executed by the CPU 392, the CPU 392 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 308, 310 and the holding chambers 316, 318. In other examples, more or fewer transfer chambers (e.g., one transfer chamber) and/or more or fewer holding chambers (e.g., no holding chambers) may be implemented as a transfer apparatus in a processing system.

Processes may generally be stored in the memory of the system controller 390 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

Embodiments of the disclosure are directed to a non-transitory computer readable medium. In one or more embodiments, the non-transitory computer readable medium includes instructions that, when executed by a controller of a processing chamber, causes a processing chamber to perform the operations of any of the methods (e.g., gapfill method 100) described herein. In one or more embodiments, the controller causes a processing chamber to perform the operations of deposition method 100. In one or more embodiments, the controller causes the processing chamber to perform the operations of depositing a nucleation underlayer on a substrate surface having at least one feature therein (operation 110). The at least one feature comprises at least one surface defining a via having a bottom surface and at least one sidewall. In one or more embodiments, the controller causes the processing chamber to deposit a metal liner on the substrate surface (operation 120).

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of metal gapfill, the method comprising:
exposing a substrate surface with at least one feature therein to a nucleation presoak to form a nucleation underlayer, the feature extending a depth from the substrate surface to a bottom and having two sidewalls;
depositing a metal liner on the nucleation underlayer by physical vapor deposition (PVD); and
depositing a metal gapfill on the metal liner and the nucleation underlayer.

2. The method of claim 1, wherein the aspect ratio of the at least one feature is at least 5:1.

3. The method of claim 1, wherein the metal liner and the metal gapfill comprise tungsten.

4. The method of claim 1, wherein the nucleation presoak comprises a silicon compound.

5. The method of claim 4, wherein the nucleation presoak consists essentially of silane (SiH₄).

6. The method of claim 1, wherein the nucleation presoak comprises a boron compound.

7. The method of claim 6, wherein the nucleation presoak consists essentially of diborane (B₂H₆).

8. The method of claim 1, wherein the nucleation underlayer comprises 1-2 monolayers of silicon and/or boron.

9. The method of claim 1, wherein the metal liner has an average thickness on the substrate surface outside of the at least one feature of about 50 Å.

10. The method of claim 1, wherein the metal gapfill is deposited by atomic layer deposition (ALD).

11. The method of claim 1, wherein the metal gapfill is deposited by chemical vapor deposition (CVD).

12. The method of claim 1, wherein the metal gapfill is formed directly on the metal liner and the nucleation underlayer.

13. The method of claim 1, wherein the nucleation underlayer does not increase the resistance of the metal liner and metal gapfill stack.

14. The method of claim 1, wherein the nucleation underlayer does not adversely affect adhesion of the metal liner and metal gapfill stack.

15. A method of metal gapfill, the method comprising:
exposing a substrate surface with at least one feature therein to a nucleation presoak comprising silane to form a silicon nucleation underlayer, the feature extending a depth from the substrate surface to a bottom and having two sidewalls;
depositing a metal liner comprising tungsten on the silicon nucleation underlayer by physical vapor deposition (PVD); and
depositing a metal gapfill comprising tungsten on the metal liner and the silicon nucleation underlayer.

16. The method of claim 15, wherein the silicon nucleation underlayer comprises 1-2 monolayers of silicon on average.

17. The method of claim 15, wherein the metal gapfill is formed directly on the metal liner and the nucleation underlayer.

18. A method of metal gapfill, the method comprising:
exposing a substrate surface with at least one feature therein to a nucleation presoak comprising diborane to form a boron nucleation underlayer, the feature extending a depth from the substrate surface to a bottom and having two sidewalls;
depositing a metal liner comprising tungsten on the boron nucleation underlayer by physical vapor deposition (PVD); and
depositing a metal gapfill comprising tungsten on the metal liner and the boron nucleation underlayer.

19. The method of claim 18, wherein the boron nucleation underlayer comprises 1-2 monolayers of boron on average.

20. The method of claim 18, wherein the metal gapfill is formed directly on the metal liner and the nucleation underlayer.
